(19) United States
(12) Patent Application Publication
(10) Pub. No.: US 2025/0183017 A1
(43) Pub. Date: Jun. 5, 2025

(54) METHOD FOR REMOVING PARTICLES OF ION BEAM ETCHING SYSTEM, AND ION BEAM ETCHING SYSTEM

(71) Applicant: JIANGSU LEUVEN INSTRUMENTS CO., LTD., Xuzhou, Jiangsu (CN)

(72) Inventors: Xiang WANG, Xuzhou, Jiangsu (CN); Xiaobo LIU, Xuzhou, Jiangsu (CN); Hongbo SUN, Xuzhou, Jiangsu (CN); Yang DOU, Xuzhou, Jiangsu (CN); Yinan WANG, Xuzhou, Jiangsu (CN); Dongdong HU, Xuzhou, Jiangsu (CN); Lu CHEN, Xuzhou, Jiangsu (CN); Kaidong XU, Xuzhou, Jiangsu (CN)

(73) Assignee: JIANGSU LEUVEN INSTRUMENTS CO., LTD., Xuzhou, Jiangsu (CN)

(21) Appl. No.: 18/723,597

(22) PCT Filed: Dec. 23, 2022
(86) PCT No.: PCT/CN2022/141484

§ 371 Date: Jun. 24, 2024

(30) Foreign Application Priority Data
Dec. 24, 2021 (CN) 202111598567.X

(51) Int. Cl. H01J 37/32; H01J 37/305

(52) U.S. Cl. CPC H01J 37/32871; H01J 37/3053; H01J 37/32862; H01J 2237/334

(57) ABSTRACT

A method and apparatus for removing particles of an ion beam etching system. The ion beam etching system includes: a first grid configured to connect a positive voltage generated by a first DC power supply; a second grid configured to connect a negative voltage generated by a second DC power supply; a third grid configured to connect a positive voltage generated by a third DC power supply; a neutralizer located above the third grid and configured to generate electrons; and an air extraction hole located below the third grid and connected to a molecular pump. The first grid and the second grid are configured to accelerate plasma in a reaction chamber, and the third grid is located on a side of the second grid away from the first grid.

This application claims priority to Chinese Patent Application No. 202111598567.X, titled “METHOD AND APPARATUS FOR REMOVING PARTICLES OF ION BEAM ETCHING SYSTEM”, filed on Dec. 24, 2021 with the China National Intellectual Property Administration, which is incorporated herein by reference in its entirety.

### FIELD

The present disclosure relates to a method for removing particles of an ion beam etching system and an ion beam etching system, in order to transform a structure of an ion beam etching device and to efficiently remove particles produced by the ion beam etching system without opening a cavity.

### BACKGROUND

Ion beam etching (IBE) is a purely physical bombardment process to achieve the purpose of etching: filling inert gases such as argon, krypton, and xenon into an ion source discharge chamber and ionizing the inert gases to form plasma; drawing out and accelerating the plasma in ion beam by a grid; then the ion beam with a certain energy entering a working chamber, shooting towards a solid surface, and hitting atoms of the solid surface to cause the atoms to sputter. When etching complex systems containing various metals and oxides, debris and particles of various sizes may be sputtered in the reaction chamber. In addition, the air pressure in the reaction chamber is low, and larger and farther non-volatile particles are difficult to be pumped away by molecular pumps, causing by-products to deposit on inner walls of the chamber. This not only results in particle contamination, but also reduces the repeatability of the process over time. Therefore, the plasma processing chamber needs to be cleaned. However, cleaning would cause process interruption and reduce the production efficiency of plasma processing equipment in actual use.

At present, various measures have been provided by research on the accumulation of polymers on the inner walls of the etching chamber during the etching process in the industry and have achieved good improvement effects. Cleaning methods of wafer-less automatic dry etching are used most widely, generally use fluorine-rich gases such as NF₃ to remove inorganic polymers, use oxygen-rich gases such as O₂ to remove organic polymers, and deposit a layer of silica-like polymers on the inner walls of the etching chamber after cleaning. These wafer-less self-cleaning steps may effectively improve the deposition in the chamber. However, there is no effective solution for processing the debris such as metal particles generated during the IBE process in the industry. Opening the chamber may only be performed at certain intervals, which seriously affects equipment productivity.

The patent with Publication number CN105097445B provides a method for removing particles in an etching chamber, comprising: forming a coating in a dry etching chamber, placing a wafer in the dry etching chamber, etching the metal-containing layer of the wafer, and removing the wafer from the dry etching chamber. After the wafer is removed from the dry etching chamber, the coating is removed. This patent is equivalent to affixing a protective film to the inner wall of the chamber and removing the protective film after the process. Cleaning still needs to open the chamber, so the inner wall of the chamber may be maintained to be clean to prevent particles from adhering.

The patent application with Publication number CN101727025A discloses a method for removing photoresist residues and etching reactant particles, comprising: sequentially forming a to-be-etched layer and a patterned photoresist layer on a semiconductor substrate; etching the to-be-etched layer by using the photoresist layer as a mask; removing the photoresist layer through ashing method; placing the semiconductor substrate with each layer into a solution spraying circulation pool and removing photoresist residues by spraying with a first solution, where the first solution with the photoresist residues flows out from the solution spraying circulation pool; introducing a second solution to spray to remove etching reactant particles remained in the etching process, where the second solution with the etching reactant particles flows out from the solution spraying circulation pool. The invention ensures that photoresist residues and etching reactant particles can be effectively removed, and improves the performance of semiconductor devices. This invention is aimed at how to remove particles from the etched wafer and protect the required wafer layer from damage, which is not related to the present disclosure.

The patent with Publication number CN109216241B discloses an intelligent self-cleaning method for etching by-products, which is suitable for the dry etching process of semiconductors, provides a process control system and a dry etching device, and also comprises following steps: in step S1, before the dry etching process corresponding to the dry etching equipment starts, collecting the first process parameters in the dry etching process before the dry etching equipment is executed by the process control system; in step S2, obtaining the second process parameters for self-cleaning the dry etching equipment by the process control system based on the first process parameters; in step S3, performing a self-cleaning process on the dry etching equipment by the process control system according to the second process parameters; and in step S4, executing the corresponding dry etching process through dry etching equipment, returning to step S1 after the dry etching process is completed. This invention reduces the source of etching defect particles caused by polymer accumulation during the etching process, and improves the first effect problem in wafer batch operations. This invention provides a process control system that reads the process parameters of different batches, compares them with standard values, and then performs self-cleaning to ensure the consistency of process conditions. As for self-clean, it is not explained and has little to do with the present disclosure.

### SUMMARY

Conventional ion beam etching device in the semiconductor field utilizes inert gas for physical bombardment, is not suitable for ICP (inductively coupled plasma etching) wafer-less cleaning process, and can only clean and remove particles by opening the chamber, which seriously affects the production capacity. In order to overcome shortcomings of the conventional technology, a method and apparatus for removing particles in an ion beam etching system is provided according to embodiments of the present disclosure. By additionally providing a metal grid, a positive voltage is applied to the metal grid to suck away charged particles, which are formed by negatively charging particles in the chamber by electrons emitted by the neutralizer of the ion beam etching system. Thus, particles can be removed efficiently without opening the chamber, and the production efficiency of plasma treatment equipment is improved.

In order to solve the above technical problems, the present disclosure is implemented as follows.

An ion beam etching system additionally provides a third grid on the basis of the reaction chamber of the conventional ion beam etching system. Specifically, the third grid is fixed on the inner wall of the reaction chamber through connecting threaded holes provided at two ends of the third grid and insulators. The third grid is connected to a DC power supply to generate a positive voltage, and the voltage value is adjusted within 100 kv according to sizes of to-be-removed particles.

In one embodiment, the third grid c is disposed at the bottom of the chamber in order to improve efficiency.

The third grid c is made of hard metal, such as molybdenum or nickel. A mesh size is less than 5 mm, which facilitates passage of particles with different sizes. A shape of the third grid c may be circular, square or irregular shape.

In the above method of removing particles from the ion beam etching system, when the etching process is completed and the particles of the ion beam etching system need to be processed, an ion source of the ion beam etching system is disconnected first, then a lower electrode is rotated 90 degrees to a position perpendicular to the third grid c, and the neutralizer is turned on for a period of time. A large number of electrons generated by the neutralizer may attach to the particles, making the various particles sputtered in the reaction chamber negatively charged. Then a positive voltage is applied to the third grid c through the third DC power supply c. In this case, the negatively charged particles will move toward the third grid c under the action of the electric field. An air extraction hole of a molecular pump is located below the third grid c. Thus, the particles will pass through the mesh of the third grid c, be pumped away by the molecular pump and be discharged out of the chamber, which facilitates rapid and effective removal of particles and prevents the deposition of particles inside the reaction chamber.

The ion source is a radio frequency excitation ion source, is configured to generate ion beams in etching process, and consists of a radio frequency (RF) power supply, a matcher, a radio frequency (RF) coil, a grounding capacitor C, a discharge chamber, a first DC power supply a, a first filter a, a second DC power supply b, a second filter b, and a second grid b.

Alternatively, the ion source may be a Kaufman-type ion source or an ECR ion source.

The RF power supply is connected to the RF coil through a matcher, ionizes gas introduced into the discharge chamber, and then leads out the ion beam through two-layer grid. This is the principle of ion beam generation in the ion beam etching system.

The lower electrode is the stage of the wafer in the ion beam etching system, and may rotate and/or revolve to change the incident angle of the ion beam, such that etching at different angles on both sides may be achieved. In a case of removing particles, the lower electrode is rotated 90 degrees to a position perpendicular to the grid c. On the one hand, the deposition of particles on surfaces of the lower electrode can be reduced. On the other hand, the grid c is completely exposed in the reaction chamber, such that particles can be adsorbed thoroughly.

The neutralizer is configured to excite and generate electrons, which attach to the particles in the reaction chamber to make them negatively charged. The neutralizer may be a radio frequency neutralizer, a hot cathode neutralizer, a hollow cathode neutralizer, or an electron cyclotron resonance neutralizer.

The present disclosure has following positive effects:
(1) The present disclosure additionally provides a grid to make the particles negatively charged on a condition of the ion beam etching system containing a neutralizer that can provide a large number of electrons. In a case that other etching systems do not have this environment, efficient particle removal may not be achieved even if a grid is additionally provided.
(2) The present disclosure is easy to implement. The grid is only need to be fixed in the chamber with screws and fasteners, and connects to the DC power supply. The grid is placed at the bottom to improve efficiency.
(3) The particle removal efficiency of the present disclosure can be improved by increasing the number of electrons generated by the neutralizer and increasing the voltage value of the DC power supply c. The greater the number of electrons is, the easier they are to be collided and adsorbed by particles. The higher the voltage of the grid c is, the stronger the electric field generated. Even larger particles far away from the grid can move toward the grid under the action of the electric field, and are thus pumped away and discharged out of the chamber by the molecular pump.
(4) The working principle of the present disclosure is different from that of an electrostatic precipitator. The electrostatic precipitator maintains an electrostatic field sufficient to ionize gas through high-voltage direct current on a metal anode and a metal cathode with significantly large differences in curvature radii. The electrons, anions and cations generated after gas ionization are adsorbed on the dust passing through the electric field, causing the dust to gain charges. Under the action of the electric field force, the charged dust moves to the electrodes with opposite polarity and deposits on the electrodes to achieve the purpose of separation of the dust and the gas.

### BRIEF DESCRIPTION OF THE DRAWINGS

FIG. 1 is a schematic structural diagram of an ion beam etching system according to an embodiment of the present disclosure.

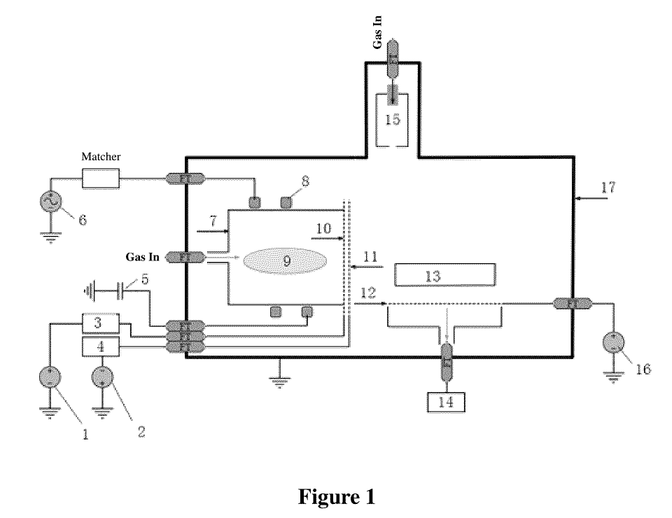

FIG. 2 is a comparative experiment of particle removal effects before and after installing the third grid c in Embodiment 1.

Reference numerals:

| | |
|---|---|
| 1: first DC power supply a; | 2: second DC power supply b; |
| 3: first filter a; | 4: second filter b; |
| 5: capacitor C; | 6: RF power supply; |
| 7: discharge chamber; | 8: RF coil; |
| 9: plasma; | 10: first grid a; |
| 11: second grid b; | 12: third grid c; |
| 13: lower electrode; | 14: molecular pump; |
| 15: neutralizer; | 16: third DC power supply c; |
| 17: reaction chamber. | |

### DETAILED DESCRIPTION OF EMBODIMENTS

The present disclosure will be further described in detail below in conjunction with specific embodiments.

### Embodiment 1

A schematic structural diagram of an ion beam etching system is provided according to an embodiment of the present disclosure. The ion beam etching system includes: a first grid, a second grid, a third grid, a neutralizer and an air extraction hole. The first grid and the second grid are configured to accelerate plasma in a reaction chamber. The third grid is located on a side of the second grid away from the first grid, the neutralizer is located above the third grid, and the air extraction hole is located below the third grid and connected to a molecular pump for extracting gas from the reaction chamber. That is, a layer of grid may be additionally provided at a bottom of the reaction chamber of the ion beam etching system. The material of the grid may be a conductive material, such as a metal material. The grid may be referred to as the third grid c or the metal grid. The grid is connected to a DC power supply to generate a positive voltage, and the voltage value is adjusted within 100 kv according to sizes of to-be-removed particles.

Threaded holes are provided at two ends of the third grid, and the threaded holes are configured to fix the third grid on an inner wall of the reaction chamber by connecting with an insulator. The third grid is disposed at the bottom of the reaction chamber, and an angle between an extending direction of the third grid and the inner wall of the bottom of the reaction chamber is less than a preset angle. The preset angle may be smaller, such that the extending direction of the third grid is parallel or nearly parallel to the inner wall of the bottom of the reaction chamber. An extending direction of the first grid is parallel to an extending direction of the second grid, and extending directions of the first grid and the second grid are perpendicular to the extending direction of the third grid. The third grid is made of metal, such as molybdenum or nickel. The mesh size of the third grid is less than 5 mm. The shape of the third grid is circular, square or irregular shape.

The neutralizer is a radio frequency neutralizer, a hot cathode neutralizer, a hollow cathode neutralizer or an electron cyclotron resonance neutralizer. The ion beam etching system further includes a lower electrode located directly above the third grid, the lower electrode is configured for placing the wafer and moving above a side of the third grid before the positive voltage is applied to the third grid.

When the wafer needs to be etched, the radio frequency (RF) power supply 6 is connected to the radio frequency (RF) coil 8 through a matcher. The other end of the RF coil 8 is connected to a grounded capacitor. The grounded capacitor is configured to balance a voltage at two ends of the RF coil. A gas introduced into the discharge chamber 7 is ionized to generate plasma by means of inductive coupling. The first DC power supply a applies a positive voltage to the first grid a through the first filter a to accelerate and attract the electrons in the plasma. The plasma is energized, and the positive ions in the plasma pass through the first grid a under the action of a sheath voltage. The second DC power supply b applies a negative voltage to the second grid b through the second filter b. The positive ions passing through the first grid a are accelerated through the second grid b under the action of the negative electric field to form an ion beam. The ion beam is then neutralized with the electrons generated by the neutralizer 15, and finally bombards the wafer on the surface of the lower electrode with a certain energy and angle, so that material atoms are sputtered to achieve the purpose of etching. During the etching process, the lower electrode is configured to change the incident angle of the ion beam relative to the wafer on the lower electrode by means of rotation and/or revolution.

When the etching process is completed in the ion beam etching system and the particles sputtered by the ion beam etching system need to be removed, the ion source of the ion beam etching system is disconnected first. When the lower electrode 13 is located above the third grid c, the lower electrode located above the third grid may be rotated to move above the side of the third grid. For example, the lower electrode 13 may be rotated 90 degrees to a position perpendicular to the third grid c, in this case, the extending direction of the lower electrode is perpendicular to the extending direction of the third grid (on the one hand, to reduce the deposition of particles on the surface of the lower electrode, and on the other hand, to completely expose the third grid c in the reaction chamber, particles may be adsorbed more thoroughly). The neutralizer is turned on, and a large number of electrons generated by the neutralizer 15 may attach to the particles, making various non-volatile particles sputtered in the reaction chamber negatively charged. Then a positive voltage is applied to the third grid c through the third DC power supply c, the negatively charged particles may move toward the third grid c under the action of the electric field. The air extraction hole of the molecular pump 14 is below the third grid c. Thus, the particles may pass through the mesh of the third grid c, are pumped away by the molecular pump below the third grid c, and discharged out of the chamber along pipes, thereby achieving the purpose of removing particles. The voltage value of the positive voltage applied on the third grid is adjusted within 100 kv according to sizes of the to-be-removed particles. The particle removal efficiency is improved by adjusting and increasing the number of electrons generated by the neutralizer and adjusting and increasing the voltage value of the third DC power supply connected to the third grid.

### Embodiment 2: Confirmation Experiment of Particle Removal Effect

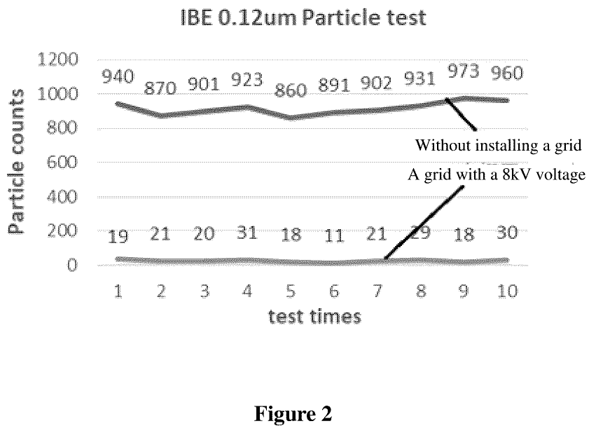

Regarding the investigation of the particle removal effect of the present disclosure, first, without installing a grid, after the ion beam etching is completed, the number of particles with a size of 0.12 um is tested with an SP1 detector, and 10 sets of detection data are recorded. The number of particles with the size of 0.12 um is generally around 900. Then, the apparatus and method are provided according to the embodiments of the present disclosure, a circular molybdenum grid with a diameter of 38 cm and a mesh diameter of 2 mm is selected, and the metal grid is fixed at the bottom of the reaction chamber (two ends of the metal grid are connected to the reaction chamber through insulators). After the process is completed, the neutralizer is turned on for 10 minutes, and then a positive voltage of 8 KV is applied through the DC power supply connected to the third grid c. After 5 minutes, the SP1 detector is configured to detect the number of particles with the size of 0.12 um. This experiment is repeated for 10 minutes and the data is recorded. In this case, the number of particles with the size of 0.12 um is generally around 20, which meets requirements of the process, as shown in FIG. 2.

In Embodiment 2, only the number of particles with the size of 0.12 um is detected for comparison reference. In fact, the particle sizes in the reaction chamber are different. Larger grids, larger grid voltage and applying time, and longer power-on time of the neutralizer can greatly improve the particle removal efficiency.

The above-mentioned specific embodiments do not limit the technical solution of the present disclosure in any form. All technical solutions obtained by equivalent substitution or equivalent transformation fall within the protection scope of the present disclosure.

1. An ion beam etching system, comprising:
a third grid, located in a reaction chamber of the ion beam etching system, wherein the third grid is configured to connect a positive voltage generated by a third DC power supply;
a first grid and a second grid, located in the reaction chamber, wherein the first grid is configured to connect a positive voltage generated by a first DC power supply, the second grid is configured to connect a negative voltage generated by a second DC power supply, the first grid and the second grid are configured to accelerate plasma in the reaction chamber, and the third grid is located on a side of the second grid away from the first grid;
a neutralizer, located above the third grid, wherein the neutralizer is configured to generate electrons; and
an air extraction hole, located below the third grid and connected to a molecular pump.

2. The ion beam etching system according to claim 1, wherein threaded holes are provided at two ends of the third grid and configured to fix the third grid on an inner wall of the reaction chamber by connecting with an insulator.

3. The ion beam etching system according to claim 1, wherein the third grid is disposed at a bottom of the reaction chamber, and an angle between an extending direction of the third grid and a bottom inner wall of the reaction chamber is less than a preset angle.

4. The ion beam etching system according to claim 1, wherein an extending direction of the first grid is parallel to an extending direction of the second grid, and extending directions of the first grid and the second grid are perpendicular to an extending direction of the third grid.

5. The ion beam etching system according to claim 1, wherein the neutralizer is a radio frequency neutralizer, a hot cathode neutralizer, a hollow cathode neutralizer or an electron cyclotron resonance neutralizer.

6. The ion beam etching system according to claim 1, wherein a material of the third grid is metal.

7. The ion beam etching system according to claim 6, wherein a material of the third grid is molybdenum or nickel.

8. The ion beam etching system according to claim 1, wherein a mesh size of the third grid is less than 5 mm.

9. The ion beam etching system according to claim 1, wherein a shape of the third grid is circular, square or irregular shape.

10. The ion beam etching system according to claim 1, further comprising:
a lower electrode, located directly above the third grid, wherein the lower electrode is configured to place a wafer and move above a side of the third grid before the positive voltage generated by the third DC power supply is applied to the third grid.

11. A method for removing particles of an ion beam etching system, applied to an ion beam etching system,
wherein the ion beam etching system comprises:
a third grid, located in a reaction chamber of the ion beam etching system, wherein the third grid is configured to connect a positive voltage generated by a third DC power supply;
a first grid and a second grid, located in the reaction chamber, wherein the first grid is configured to connect a positive voltage generated by a first DC power supply, the second grid is configured to connect a negative voltage generated by a second DC power supply, the first grid and the second grid are configured to accelerate plasma in the reaction chamber, and the third grid is located on a side of the second grid away from the first grid;
a neutralizer, located above the third grid, wherein the neutralizer is configured to generate electrons; and
an air extraction hole, located below the third grid and connected to a molecular pump;
wherein the method comprises:
after an etching process of the ion beam etching system is completed, disconnecting an ion source of the ion beam etching system, and turning on the neutralizer, wherein the electrons generated by the neutralizer are configured to attach to particles that need to be removed;
controlling the third grid to be connected to the positive voltage generated by the third DC power supply to provide an electric field, wherein particles negatively charged moves toward the third grid under an action of the electric field, and the air extraction hole is configured to extract the particles charged negatively.

12. The method according to claim 11, wherein a voltage value of the positive voltage applied on the third grid is adjusted within 100 kv according to sizes of the particles that need to be removed.

13. The method according to claim 11, further comprising:
rotating a lower electrode located directly above the third grid to move above the side of the third grid.

14. The method according to claim 13, wherein when the lower electrode is located above the side of the third grid, an extending direction of the lower electrode is perpendicular to an extending direction of the third grid.

15. The method according to claim 11, wherein during the etching process, a lower electrode is configured to change an incident angle of an ion beam relative to a wafer on the lower electrode by means of rotation and/or revolution.

16. The method according to claim 11, further comprising:
adjusting and increasing a number of the electrons generated by the neutralizer, and adjusting and increasing a voltage value of the third DC power supply connected with the third grid, to improve a particle removal efficiency.

17. The method according to claim 11, wherein during the etching process,
ionizing a gas introduced into a discharge chamber to generate plasma by means of inductive coupling;
applying a positive voltage to the first grid through a first filter by the first DC power supply to accelerate and attract electrons in the plasma to energize the plasma, wherein positive ions in the plasma pass through the first grid under an action of a sheath voltage;
applying a negative voltage to the second grid through a second filter by the second DC power supply, where the positive ions passing through the first grid accelerate through the second grid under an action of a negative electric field to form an ion beam; and
neutralizing the ion beam with the electrons generated by the neutralizer, wherein the ion beam bombards the wafer on a surface of the lower electrode with a certain energy and angle to make material atoms to sputter, achieving a purpose of etching.
